(19) United States
(12) Patent Application Publication
(10) Pub. No.: US 2011/0065227 A1
(43) Pub. Date: Mar. 17, 2011

(54) COMMON LASER MODULE FOR A PHOTOVOLTAIC PRODUCTION LINE

(75) Inventors: Tzay-Fa Su, San Jose, CA (US); David Morishige, Los Gatos, CA (US); David Tanner, San Jose, CA (US); Chris Eberspacher, Palo Alto, CA (US)

(73) Assignee: APPLIED MATERIALS, INC., Santa Clara, CA (US)

(21) Appl. No.: 12/559,838

(22) Filed: Sep. 15, 2009

(51) Int. Cl. H01L 31/18; B23K 26/00

(52) U.S. Cl. 438/68; 219/121.68; 438/463; 257/E31.11

(57) ABSTRACT

Embodiments of the present invention generally relate to an automated production line using a common laser scribe module for providing consistent scribe lines in multiple layers during the formation of thin film photovoltaic modules. The common laser scribe module includes a plurality of identical, programmable laser tools configured to emit radiation at a common wavelength. Substrates flowing through the production line are tracked by a system controller, which identifies available laser tools within the common laser scribe module and routes substrates to available tools for scribing features in one or more layers disposed on the substrates. The system controller also sets and controls laser parameters, such as power, pulse frequency, pulse width, and laser pattern, in order to accurately and consistently produce scribed lines in the appropriate material layer of the substrate.

### BACKGROUND OF THE INVENTION

1. Field of the Invention

Embodiments of the present invention generally relate to a production line for the fabrication of thin film photovoltaic modules. In particular, embodiments of the present invention relate to an automated production line using a common module of laser scribe tools for providing consistent scribe lines in multiple layers in the formation of thin film photovoltaic modules.

2. Description of the Related Art

Photovoltaic (PV) cells or solar cells are devices that convert sunlight into direct current (DC) electrical power. Typical thin film solar cells have a PV layer comprising one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Thin film solar cells are typically formed in series on a large area substrate to form a solar module. The solar modules are formed by scribing trenches in the various thin film layers deposited on the large area substrate during the fabrication process to both isolate and electrically connect the solar cells in series. In order to maintain consistency and throughput, state of the art solar module production lines use different laser modules at various locations in the production line. This is in part due to the use of particular wavelength lasers used for scribing trenches through different film layers in the formation of the solar cell modules. As a result, state of the art solar cell production lines have lengthy, inflexible process routes that consume a considerable amount of costly fabrication facility space and have a higher production line cost-of-ownership due to the requirement to house multiple different spare parts.

Therefore, there is a need for a process and system for fabricating solar modules incorporating a common module of laser scribe tools to decrease cost and facility space requirements, while improving the various scribing processes, system flexibility, and overall system throughput.

### SUMMARY OF THE INVENTION

In one embodiment of the present invention, a laser scribe module for scribing a series of trenches in multiple material layers, including at least a front contact layer, a photovoltaic layer, and a back contact layer, deposited on a substrate, comprises an automation device configured to receive and transport the substrate within the module, one or more reading devices configured to scan a unique reference designator assigned to the substrate, a plurality of laser scribing tools, each configured to emit radiation at substantially the same wavelength, and a system controller configured to receive information from the one or more reading devices, identify the material layer needing to be scribed, send commands to the automation device to transport the substrate to one of the plurality of laser scribing tools, and configure parameters of the laser scribing tool for scribing the identified material layer.

In another embodiment, a process for scribing lines in multiple layers of a solar cell device comprises receiving a substrate having one or more material layers disposed thereon into a laser scribe module, wherein the laser scribe has a plurality of laser scribe tools disposed therein, each laser scribe tool configured to emit radiation at substantially the same wavelength, transferring the substrate to an available laser scribe tool via an automation device and a system controller, setting parameters of the available laser scribe tool based on a top material layer disposed on the substrate via the system controller, wherein the top material layer is selected from the list consisting of a front contact layer, a photovoltaic layer, and a back contact layer, and scribing a series of lines into the top material layer via the available laser scribe tool and the system controller.

In another embodiment, a system for fabricating solar cell modules comprises a loading module configured to receive a substrate having a front contact layer disposed thereon, a first processing module configured to receive the substrate having the front contact layer disposed thereon with a series of trenches scribed through the front contact layer and deposit a photovoltaic layer over the scribed front contact layer, a second processing module configured to receive the substrate having the photovoltaic layer disposed thereon with a series of trenches scribed through the photovoltaic layer and deposit a back contact layer over the scribed photovoltaic layer, a common laser module having a plurality of laser tools for scribing the series of lines in each layer deposited on the substrate, wherein each laser tool is configured to emit radiation at substantially the same wavelength, and a system controller configured to set and control parameters of each of the laser tools based on the top layer deposited on the substrate needing to be scribed.

In yet another embodiment of the present invention, a process for fabricating solar cell modules comprises receiving a substrate having a transparent conducting oxide layer deposited thereon into a common laser module having a plurality of laser scribing tools, wherein each laser scribing tool is configured to emit radiation at substantially the same wavelength, transferring the substrate to a first available laser scribing tool via an automation device and a system controller, setting at least a laser pulse frequency of the first available laser scribing tool via the system controller, scribing a series of trenches through the transparent conducting oxide layer, transferring the substrate into a first processing module having at least one cluster tool with at least one chamber via the automation device, depositing one or more photovoltaic layers over the scribed transparent conducting oxide layer, transferring the substrate having the one or more photovoltaic layers disposed thereon to a second available laser scribing tool within the common laser module via the automation device, setting at least a laser pulse frequency of the second available laser scribing tool via the system controller, scribing a series of trenches through the one or more photovoltaic layers, transferring the substrate into a second processing module having at least one deposition chamber, depositing a back contact layer over the scribed photovoltaic layers, transferring the substrate having the back contact layer deposited thereon to a third available laser scribing tool within the common laser module via the automation device, setting at least a laser pulse frequency of the third available laser scribing tool via the system controller, and scribing a series of trenches through the back contact layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified, schematic flow chart illustrating one embodiment of a process sequence including a plurality of processes used to form a solar module using a solar module production line.

FIG. 2 is a simplified, schematic plan view of one embodiment of the solar cell module production line illustrating process modules for use with the process sequence of FIG. 1.

FIG. 3 is a schematic plan view of a solar module having a plurality of solar cells formed on a substrate.

FIG. 4 is a schematic, cross-sectional view of a portion of the solar module along section line 4-4 shown in FIG. 3.

FIG. 5 is a schematic plan view of the common laser module according to one embodiment of the present invention.

FIG. 6A is a schematic plan view of a laser scribe tool according to the present invention.

FIG. 6B is a schematic, cross-sectional view of the laser scribe tool in FIG. 6A.

FIG. 6C is a schematic depiction of a laser device described herein.

FIG. 6D is a schematic, cross-sectional view of an optical fiber from the laser device in FIG. 6C.

For clarity, identical reference numerals have been used, where applicable, to designate identical elements that are common between figures. It is contemplated that features of one embodiment may be incorporated in other embodiments without further clarification.

### DETAILED DESCRIPTION

Embodiments of the present invention generally relate to an automated production line using a common laser scribe module for providing consistent scribe lines in multiple layers during the formation of thin film photovoltaic modules. The common laser scribe module includes a plurality of identical, programmable laser tools configured to emit radiation at a common wavelength. Substrates flowing through the production line are tracked by a system controller, which identifies available laser tools within the common laser scribe module and routes substrates to available tools for scribing features in one or more layers disposed on the substrates. The system controller also sets and controls laser parameters, such as power, pulse frequency, pulse width, and laser pattern, in order to accurately and consistently produce scribed lines in the appropriate material layer of the substrate.

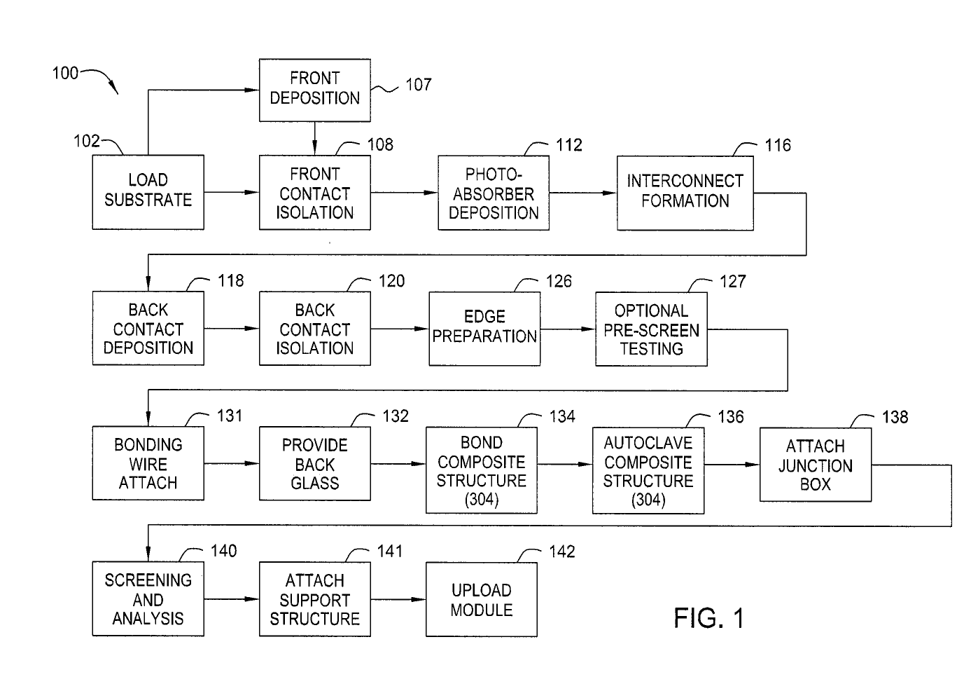

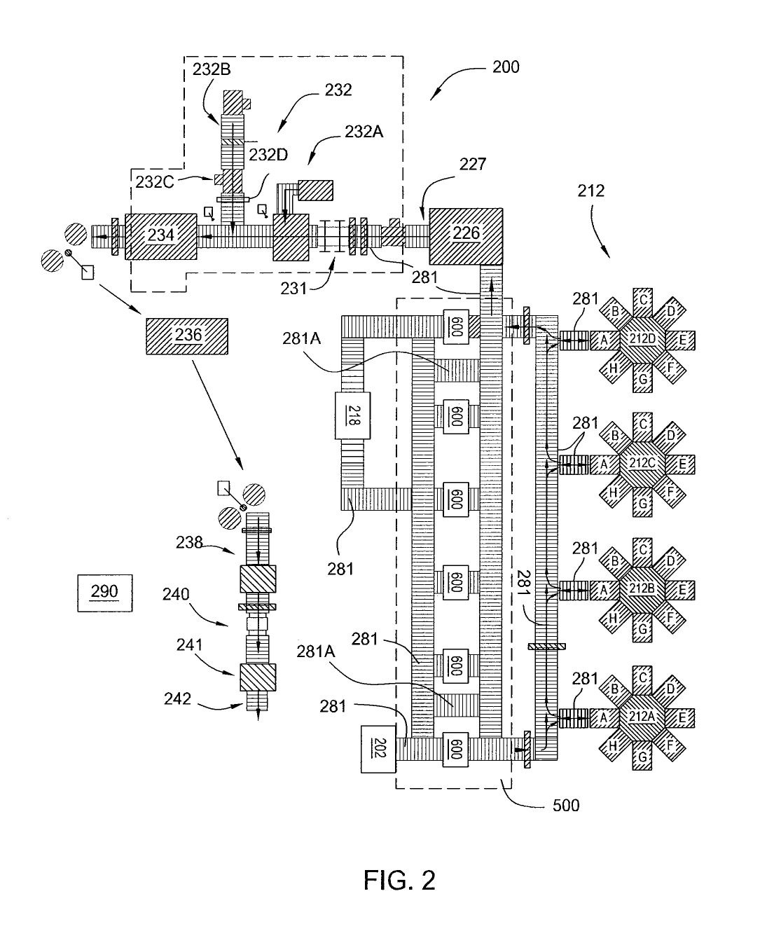

FIG. 1 is a simplified, schematic flow chart illustrating one embodiment of a process sequence 100 including a plurality of processes used to form a solar module 300 using a solar module production line 200. FIG. 2 is a simplified, schematic plan view of one embodiment of the production line 200 illustrating process modules and other aspects of the system design.

In general, a system controller 290 may be used to control one or more components found in the production line 200. The system controller 290 generally facilitates the control and automation of the overall production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete production line 200.

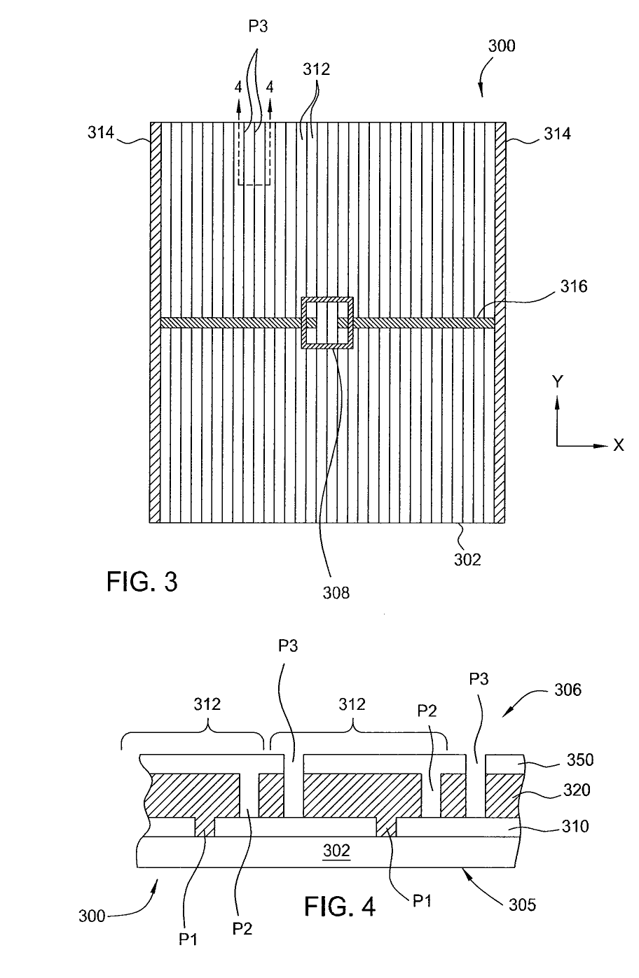

FIG. 3 is a schematic plan view of a solar module 300 having a plurality of solar cells 312 formed on a substrate 302. The plurality of solar cells 312 are electrically connected in series and are electrically connected to side busses 314 located at opposing ends of the solar module 300. A cross-buss 316 is electrically connected to each of the side busses 314 to collect the current and voltage generated by the solar cells 312. A junction box 308 acts as an interface between leads (not shown) from the cross-busses 316 and external electrical components that will connect to the solar module 300, such as other solar modules or a power grid.

In order to form a desired number and pattern of solar cells 312 on the substrate 302, a plurality of scribing processes may be performed on material layers formed on the substrate 302 to achieve cell-to-cell and cell-to edge isolation. FIG. 4 is a schematic cross-sectional view of a portion of the solar module 300 along section line 4-4 shown in FIG. 3. As shown, the solar module 300 includes the substrate 302, such as a glass substrate, polymer substrate, metal substrate, or other suitable substrate, having a front surface 305 with thin films formed over the substrate 302 on a back surface 306 opposite the front surface 305 of the substrate 302. In one embodiment, the substrate 302 is a glass substrate that is about 2200 mm×2600 mm×3 mm in size. The solar module 300 further includes a front contact layer 310 formed over back surface 306 of the substrate 302. The front contact layer 310 may be any optically transparent and electrically conductive film, such as a transparent conducting oxide (TCO), formed to serve as a front contact electrode for the solar cells 312. Examples of TCO include zinc oxide (ZnO), aluminum zinc oxide (AZO), and tin oxide (SnO). The solar module 300 further includes a photovoltaic (PV) layer 320 formed over the front contact layer 310 and a back contact layer 350 formed over the PV layer 320.

The PV layer 320 may include a plurality of silicon film layers that includes one or more p-i-n junctions for converting energy from incident photons into electricity through the PV effect. In one configuration, the PV layer 320 comprises a first p-i-n junction having a p-type amorphous silicon layer, and intrinsic type amorphous silicon layer formed over the p-type amorphous silicon layer, and an n-type amorphous silicon layer formed over the intrinsic type amorphous silicon layer. In one example, the p-type amorphous silicon layer is formed to a thickness between about 60 Å and about 300 Å, the intrinsic type amorphous silicon layer is formed to a thickness between about 1500 Å and about 3500 Å, and the n-type amorphous semiconductor layer is formed to a thickness between about 100 Å and about 500 Å. In one embodiment, instead of the n-type amorphous silicon layer, an n-type microcrystalline semiconductor layer is formed to a thickness between about 100 Å and about 400 Å.

In another configuration, the PV layer 320 further comprises a second p-i-n junction over the first p-i-n junction. In one example, the second p-i-n junction comprises a p-type microcrystalline silicon layer formed to a thickness from about 100 Å and about 400 Å, an intrinsic type microcrystalline silicon layer formed to a thickness between about 10,000 Å and about 30,000 Å over the p-type microcrystalline silicon layer, and an n-type amorphous silicon layer formed over the intrinsic type microcrystalline silicon layer at a thickness between about 100 Å and about 500 Å.

The back contact layer 350, which is formed over the PV layer 320, may include one or more conductive layers adapted to serve as a back electrode for the solar cells 312. In one embodiment, the back contact layer 350 may comprise a series of conductive layers that may include metals and/or conductive transparent oxide layers. Examples of materials that may comprise the back contact layer 350 include, but are not limited to aluminum (Al), silver (Ag), titanium (Ti), chromium (Cr), gold (Au), copper (Cu), platinum (Pt), alloys thereof, or combinations thereof. In one embodiment, the back contact layer 350 comprises a transparent conducting oxide (TCO) layer that is disposed over the PV layer 320 and one or more metal layers formed over the TCO layer. In one example, the TCO layer includes an aluminum zinc oxide (AZO) layer, and the one or more metal layers comprises an aluminum layer and a nickel vanadium alloy layer that has a thickness between about 1000 Å and about 3000 Å. In another example, the back contact layer 350 comprises an aluminum and nickel vanadium multilayer film that has a thickness between about 1000 Å and about 3000 Å.

Three scribing steps may be performed to produce trenches P1, P2, and P3, which are required to form a high efficiency solar cell device, such as the solar module 300. Although formed together on the substrate 302, the individual cells 312 are isolated from each other by the insulating trench P3 formed in the back contact layer 350 and the PV layer 320. In addition, the trench P2 is formed in the PV layer 320 so that the back contact layer 350 is in electrical contact with the front contact layer 310. In one embodiment, the insulating trench P1 is formed by laser removal of a portion of the front contact layer 310 prior to the deposition of the PV layer 320 and the back contact layer 350. Similarly, in on embodiment, the trench P2 is formed in the PV layer 320 by the laser scribe removal of a portion of the PV layer 320 prior to the deposition of the back contact layer 350. Finally, in one embodiment, the trench P3 is formed by the laser removal of portions of the back contact layer 350 and the PV layer 320.

The lines of trenches P1, P2, and P3 are typically formed by a pulsed laser source capable of a frequency below about 80 kHz. The laser source is typically pulsed at a desired frequency as the substrate 302 is linearly translated, resulting in a series of overlapping regions or “spots” of ablated material in the desired layer on the substrate 302. In conventional laser scribing of the P1 trench, a 1064 nm laser source is pulsed at a frequency of about 60 kHz as the substrate 302 is linearly translated at a rate of about 1 m/s. In contrast, the formation of the P2 and P3 trenches are typically provided by pulsing a 532 nm laser at a frequency of about 20 kHz as the substrate 302 is linearly translated at a rate of about 1 m/s. Using conventional laser tools and laser pulsing techniques demands the use of a different wavelength laser for ablating the front contact layer material than the PV layer material or the back contact layer material to achieve reasonable throughput in the solar cell formation process. For instance, the use of a conventional 532 nm wavelength laser and conventional pulsing techniques on the front contact layer 310 does not result in fully ablated lines of trenches P1 because the material (e.g., TCO) of which the front contact layer 310 is comprised, absorbs very little energy at wavelengths around 532 nm. In contrast, the use of a 1064 wavelength laser during the formation of the P2 and P3 trenches would result in unacceptable removal of the front contact layer 310.

To avoid confusion relating to the actions specifically performed on the substrates 302 in the following description, a substrate 302 having one or more of the deposited layers (e.g., the front contact layer 310, the PV layer 320, or the back contact layer 350) and/or one or more internal electrical connections (e.g., side buss 314, cross-buss 316) disposed thereon is referred to as a device substrate 303. Similarly, a device substrate 303 that has been bonded to a back glass substrate using a bonding material is referred to as a composite solar cell structure 304.

### General Solar Module Formation

Referring to FIGS. 1 and 2, the process sequence 100 generally starts at step 102 in which a substrate 302 is loaded into a loading module 202 found in the solar module production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., front contact layer 310) already deposited on a surface of the substrate 302 before it is received into the system in step 102. If a conductive layer is not deposited on the surface of the “raw” substrates then a front contact deposition step (step 107), which is discussed below, needs to be performed on a surface of the substrate 302.

In one embodiment, each substrate 302 is received with a unique, reference designator formed thereon. In one embodiment, the reference designator comprises a unique, individual marking, such as a barcode or other identification marking, which is assigned to each substrate 302. In one embodiment, the reference designator may be printed on or scribed into the substrate 302. In one embodiment, the reference designator may be scribed into the front contact layer 310 already deposited on a surface of the substrate 302 before it is received into the production line 200. In one embodiment, the reference designator may be located in an edge region of the substrate 302/303. In one embodiment, the reference designator is read via a reading device (not shown), such as a barcode or other optical reading device, during or after loading the substrate 302/303 into the loading module 202. The reference designator is then subsequently read at various locations throughout the production line 200, and the identification information communicated to the system controller 290, where it is correlated with other processing information and stored. The system controller 290 then uses the identification information provided on the reference designator to track the movement of each substrate 302/303, control the movement and positioning of each substrate 302/303 in the production line 200, and control the processes performed on each individual substrate 302/303.

Referring to FIGS. 1 and 2, in one embodiment, prior to performing step 108 the substrate 302 is transported to a front end processing module (not illustrated in FIG. 2) in which a front contact formation step 107 is performed on the substrate 302. In one embodiment, the front end processing module is similar to the processing module 218 discussed below. In step 107, one or more substrate front contact formation steps may include one or more preparation, etching and/or material deposition steps that are used to form the front contact regions on a bare solar cell substrate 302. In one embodiment, step 107 generally comprises one or more physical vapor deposition (PVD) steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more CVD steps are used to form the front contact region on a surface of the substrate 302.

Next, the device substrate 303 is transported via the automation device 281 to a common scribe module 500, which comprises a plurality of laser scribing tools 600. In one embodiment, as the device substrate 303 enters the common scribe module 500, its reference designator is read and communicated to the system controller 290. The system controller 290 then controls the transport of the device substrate, on the automation device 281, to one of the scribe tools 600 within the scribe module 500. Since each of the scribe tools 600 is physically identical, the system controller 290 determines which of the scribe tools 600 is available and sends commands to the automation device 281 to transport the device substrate 303 to the available laser scribe tool 600. The system controller 290 then sends commands to the specific scribe tool 600 to perform a front contact isolation step 108 on the device substrate 303 to electrically isolate different regions of the device substrate 303 surface from each other.

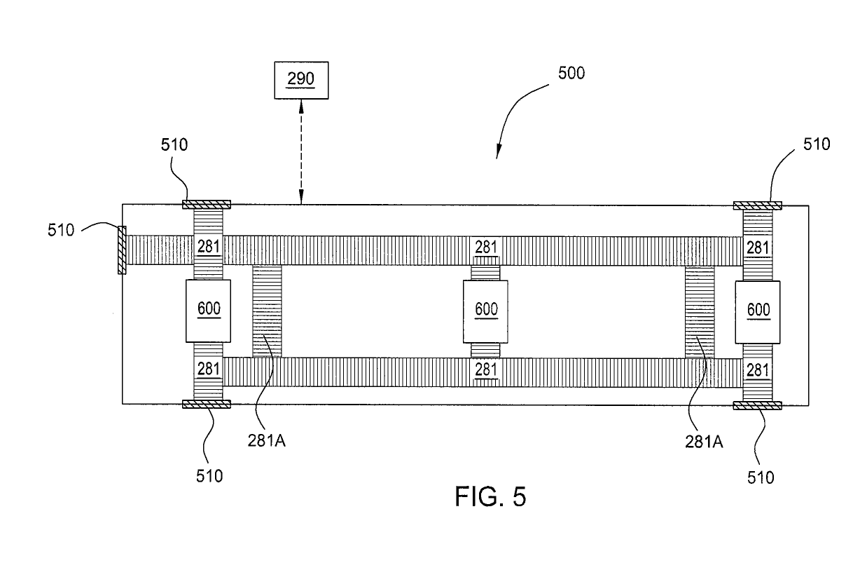

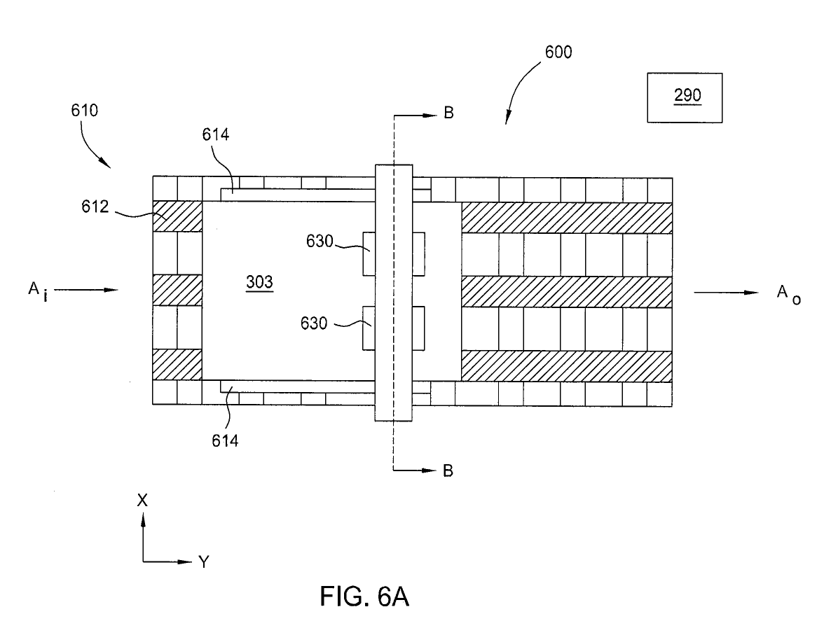

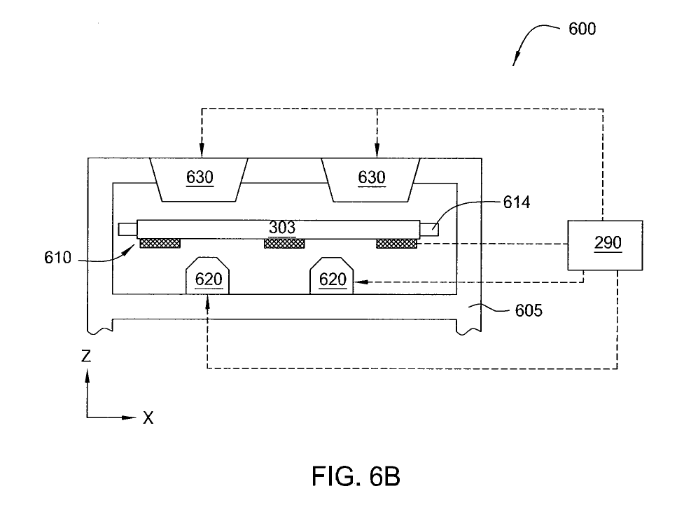

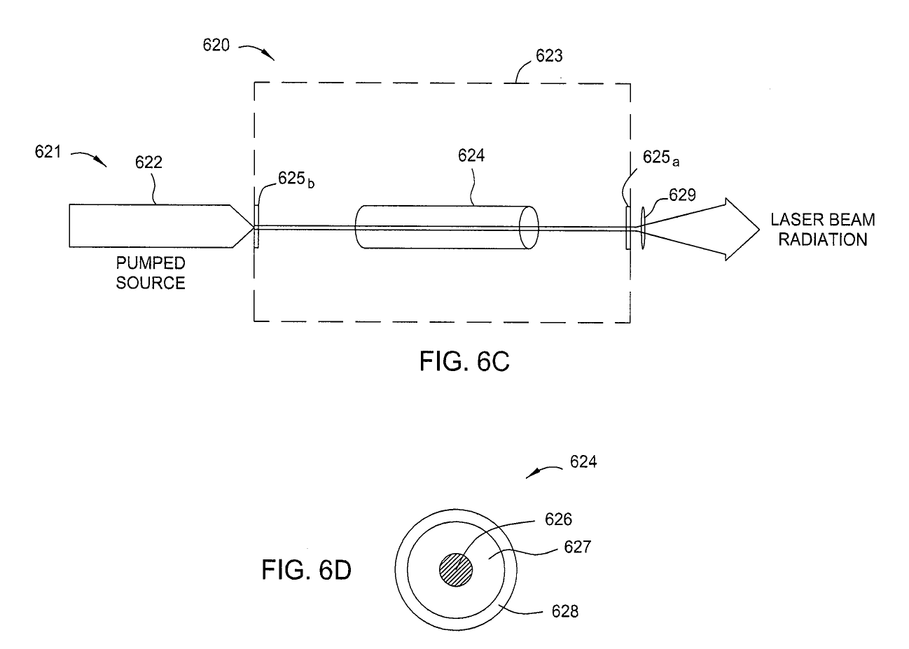

In the front contact isolation step 108, the system controller 290 selects and controls process parameters of the scribe tool 600 to perform laser scribing of a series of lines of trenches P1 into the front contact layer 310 of the device substrate 303. In one embodiment, the system controller 290 determines the process parameters based on the location from which the device substrate 303 is received. In one embodiment, the laser scribe tool 600 comprises a fiber based pulsed amplifier laser configured to emit light at a wavelength from about 510 nm to about 560 nm, such as 532 nm. In one embodiment, the system controller 290 controls the laser pulse frequency of the fiber laser within the scribe tool 600 to at least about 300 kHz or greater. In one embodiment, the system controller 290 controls the laser power output between about 5 W and about 10 W. In one embodiment, the system controller 290 controls the laser pulse width between about 2 ns and about 30 ns. In one embodiment, the system controller 290 controls the laser pulse width to 4.2 ns. In one embodiment, the system controller 290 controls the scan speed between about 1 m/s and about 5 m/s, such as about 2.5 m/s. In one embodiment, the system controller 290 controls the laser spot size to about 50 μm or less. In one embodiment, the system controller sets and controls the spacing of the lines of trenches P1. The common scribe module 500 and the scribe tools 600 contained therein are described in more detail below with respect to FIGS. 5 and 6A-6D.

Next, the device substrate 303 is transported out of the common scribe module 500 and into a processing module 212 in which step 112, which comprises one or more photovoltaic deposition steps, is performed on the device substrate 303. In step 112, the one or more photovoltaic deposition steps may include one or more preparation, etching, and/or material deposition steps that are used to form the various regions of the solar cell device. Step 112 generally comprises a series of sub-processing steps that are used to form the PV layer 320 of the solar module 300. In one embodiment, the PV layer 320 comprises one or more p-i-n junctions including amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303.

In one embodiment, each cluster tool 212A-212D comprises a load lock chamber “A” and a plurality of processing chambers “B”-“H”. In one embodiment, one of the process chambers “B”-“H” is configured to deposit a p-type silicon layer(s) of a PV layer 320 of a solar cell device and the remaining processing chambers “B”-“H” are each configured to deposit both the intrinsic type silicon layer(s) and the n-type silicon layer(s) of the PV layer. In one embodiment, the intrinsic type silicon layer(s) and the n-type silicon layer(s) of the PV layer 320 may be deposited in the same chamber without performing a passivation process, which is used to minimize cross-contamination between the deposited layers, in between the deposition steps.

In one embodiment, in cases where the solar cell device is formed to include multiple p-i-n junctions, such as a tandem junction type of the solar cell, the cluster tool 212A in the processing module 212 may be adapted to form the first p-i-n junction and at least one of the cluster tools 212B-212D are configured to form the second p-i-n junction.

In one embodiment, the reference designator on the device substrate 303 is read prior to entering and/or within the processing module 212, and identification information is communicated to the system controller 290. In one embodiment, the identification information is used by the system controller 290 to track the device substrate 303 and control the processes performed thereon within the processing module 212.

Next, the device substrate 303 is transported back to the common scribe module 500 via the automation device 281. In one embodiment, as the device substrate 303 enters the common scribe module 500, its reference designator is again read and communicated to the system controller 290. The system controller 290 then controls the transport of the device substrate 303, on the automation device 281, to one of the scribe tools 600 within the scribe module 500. Again, since each of the scribe tools 600 is physically identical, the system controller 290 determines which of the scribe tools 600 is available and sends commands to the automation device 281 to transport the device substrate 303 to the available laser scribe tool 600. The system controller 290 then sends commands to the specific scribe tool 600 to perform an interconnect formation step 116 on the device substrate 303 to isolate different regions of the device substrate 303 surface from each other. In one embodiment, the device substrate 303 is transported via a crossover conveyor 281A to allow the device substrate 303 to be transferred one of the scribe tools 600 for processing in the same direction as the previous and subsequent scribing processes.

In the interconnect formation step 116, the system controller 290 selects and controls process parameters of the scribe tool 600 to perform laser scribing of a series of lines of trenches P2 into the PV layer 320 of the device substrate 303. In one embodiment, the system controller 290 determines the process parameters based on the location from which the device substrate 303 is received. In one embodiment, the laser scribe tool 600 comprises a fiber based pulsed amplifier laser configured to emit light at a wavelength from about 510 nm to about 560 nm, such as 532 nm. In one embodiment, the system controller 290 controls the laser pulse frequency of the fiber laser within the scribe tool 600 to between about 15 kHz and about 30 kHz, such as about 20 kHz. In one embodiment, the system controller 290 controls the laser power output from about 0.2 W to about 1 W. In one embodiment, the system controller 290 controls the laser pulse width between about 1 ns and about 30 ns. In one embodiment, the system controller 290 controls the laser pulse width to 4.2 ns. In one embodiment, the system controller 290 controls the scan speed between about 0.5 m/s and about 1.5 m/s, such as about 0.83 m/s. In one embodiment, the system controller 290 controls the laser spot size to about 50 μm or less. In one embodiment, the system controller sets and controls the spacing of the lines of trenches P2, such that they are appropriately spaced from the lines of trenches P1. The common scribe module 500 and the scribe tools 600 contained therein are described in more detail below with respect to FIGS. 5 and 6A-6D.

Next, the device substrate 303 is transported to the processing module 218 in which a back contact formation step 118 is performed on the device substrate 303. In step 118, one or more substrate back contact formation steps are performed, which may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from a group consisting of zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 350. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303. In one embodiment, the reference designator on the device substrate 303 is read prior to entering and/or within the processing module 218, and identification information is communicated to the system controller 290. In one embodiment, the identification information is used by the system controller 290 to track the device substrate 303 and control the processes performed thereon within the processing module 218.

Next, the device substrate 303 is transported back to the common scribe module 500 via the automation device 281. In one embodiment, as the device substrate 303 enters the common scribe module 500, its reference designator is again read and communicated to the system controller 290. The system controller 290 then controls the transport of the device substrate 303, on the automation device 281, to one of the scribe tools 600 within the scribe module 500. Again, since each of the scribe tools 600 is physically identical, the system controller 290 determines which of the scribe tools 600 is available and sends commands to the automation device 281 to transport the device substrate 303 to the available laser scribe tool 600. The system controller 290 then sends commands to the specific scribe tool 600 to perform a back contact isolation step 120 on the device substrate 303 to isolate different regions of the device substrate 303 surface from each other.

In the back contact isolation step 120, the system controller 290 selects and controls process parameters of the scribe tool 600 to perform laser scribing of a series of lines of trenches P3 into the back contact layer 350 of the device substrate 303 to isolate regions of the plurality of solar cells 312 contained on the surface of the device substrate from each other. In one embodiment, the system controller 290 determines the process parameters based on the location from which the device substrate 303 is received. In one embodiment, the laser scribe tool 600 comprises a fiber based pulsed amplifier laser configured to emit light at a wavelength from about 510 nm to about 560 nm, such as 532 nm. In one embodiment, the system controller 290 controls the laser pulse frequency of the fiber laser within the scribe tool 600 to between about 15 kHz and about 30 kHz, such as about 20 kHz. In one embodiment, the system controller 290 controls the laser power output from about 0.2 W to about 1 W. In one embodiment, the system controller 290 controls the laser pulse width between about 1 ns and about 30 ns. In one embodiment, the system controller 290 controls the laser pulse width to 4.2 ns. In one embodiment, the system controller 290 controls the scan speed between about 0.5 m/s and about 1.5 m/s, such as about 0.83 m/s. In one embodiment, the system controller 290 controls the laser spot size to about 50 μm or less. In one embodiment, the system controller sets and controls the spacing of the lines of trenches P3, such that they are appropriately spaced from the lines of trenches P1 and P2. The common scribe module 500 and the scribe tools 600 contained therein are described in more detail below with respect to FIGS. 5 and 6A-6D.

The device substrate 303 is next transported to the seamer/edge deletion module 226 in which a substrate surface and edge preparation step 126 is used to prepare various surfaces of the device substrate 303 to prevent yield issues later on in the process. In one embodiment of step 126, the device substrate 303 is inserted into seamer/edge deletion module 226 to prepare the edges of the device substrate 303 to shape and prepare the edges of the device substrate 303. Damage to the device substrate 303 edge can affect the device yield and the cost to produce a usable solar cell device. In another embodiment, the seamer/edge deletion module 226 is used to remove deposited material from the edge of the device substrate 303 (e.g., 10-12 mm) to provide a region that can be used to form a reliable seal between the device substrate 303 and the backside glass (i.e., steps 134-136 discussed below). Material removal from the edge of the device substrate 303 may also be useful to prevent electrical shorts in the final formed solar module.

In one embodiment, a diamond impregnated belt is used to grind the deposited material from the edge regions of the device substrate 303. In another embodiment, a grinding wheel is used to grind the deposited material from the edge regions of the device substrate 303. In another embodiment, dual grinding wheels are used to remove the deposited material from the edge of the device substrate 303. In yet another embodiment, a laser ablation technique is used to remove the deposited material from the edge of the device substrate 303. In one example, a high power infrared wavelength ND:YAG laser having a spot size of about 1 mm is used to ablate a portion of the material from the edge regions of the device substrate 303. In one aspect, the seamer/edge deletion module 226 is used to round or bevel the edges of the device substrate 303 by use of shaped grinding wheels, angled and aligned belt sanders, and/or abrasive wheels.

Next the device substrate 303 is transported to the pre-screen module 227 in which optional pre-screen steps 127 are performed on the device substrate 303 to assure that the devices formed on the substrate surface meet a desired quality standard. In step 127, a light emitting source and probing device are used to measure the output of the formed solar cell device by use of one or more substrate contacting probes. If the module 227 detects a defect in the formed device it can take corrective actions or the solar cell can be scrapped.

Next the substrate 303 is transported to a bonding wire attach module 231 in which step 131, or a bonding wire attach step, is performed on the substrate 303. Step 131 is used to attach the various wires/leads required to connect the various external electrical components to the formed solar cell device. Typically, the bonding wire attach module 231 is an automated wire bonding tool that is advantageously used to reliably and quickly form the numerous interconnects that are often required to form the large solar cells formed in the production line 200. In one embodiment, the bonding wire attach module 231 is used to form the side-buss 314 (FIG. 3) and cross-buss 316 on the formed back contact layer 350 (step 118). In this configuration the side-buss 314 may be a conductive material that can be affixed, bonded, and/or fused to the back contact layer 350 found in the back contact region to form a good electrical contact. In one embodiment, the side-buss 314 and cross-buss 316 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick. The cross-buss 316, which is electrically connected to the side-buss 314 at the junctions, can be electrically isolated from the back contact layer(s) of the solar cell by use of an insulating material, such as an insulating tape. The ends of each of the cross-busses 316 generally have one or more leads that are used to connect the side-buss 314 and the cross-buss 316 to the electrical connections found in a junction box 308, which is used to connect the formed solar cell to the other external electrical components.

In the next step, step 132, a bonding material and “back glass” substrate are prepared for delivery into the solar cell formation process (i.e., process sequence 100). The preparation process is generally performed in the glass lay-up module 232, which generally comprises a material preparation module 232A, a glass loading module 232B, a glass cleaning module 232C, and a glass inspection module 232D. The back glass substrate is bonded onto the device substrate 303 formed in steps 102-131 above by use of a laminating process (step 134 discussed below). In general, step 132 requires the preparation of a polymeric material that is to be placed between the back glass substrate and the deposited layers on the device substrate 303 to form a hermetic seal to prevent the environment from attacking the solar cell during its life. Referring to FIG. 2, step 132 generally comprises a series of sub-steps in which a bonding material is prepared in the material preparation module 232A, the bonding material is then placed over the device substrate 303, and the back glass substrate is loaded into the loading module 232B. The back glass substrate is washed by the cleaning module 232C. The back glass substrate is then inspected by the inspection module 232D, and the back glass substrate is placed over the bonding material and the device substrate 303.

In the next sub-step of step 132, the back glass substrate is transported to the cleaning module 232C in which a substrate cleaning step, is performed on the substrate to remove any contaminants found on the surface of the substrate. Common contaminants may include materials deposited on the substrate during the substrate forming process (e.g., glass manufacturing process) and/or during shipping of the substrates. Typically, the cleaning module 232C uses wet chemical scrubbing and rinsing steps to remove any undesirable contaminants as discussed above.

The prepared back glass substrate is then positioned over the bonding material and partially device substrate 303 by use of an automated robotic device.

Next the device substrate 303, the back glass substrate, and the bonding material are transported to the bonding module 234 in which step 134, or lamination steps are performed to bond the backside glass substrate to the device substrate formed in steps 102-132 discussed above. In step 134, a bonding material, such as Polyvinyl Butyral (PVB) or Ethylene Vinyl Acetate (EVA), is sandwiched between the backside glass substrate and the device substrate 303. Heat and pressure are applied to the structure to form a bonded and sealed device using various heating elements and other devices found in the bonding module 234. The device substrate 303, the back glass substrate and bonding material thus form a composite solar cell structure 304 that at least partially encapsulates the active regions of the solar cell device. In one embodiment, at least one hole formed in the back glass substrate remains at least partially uncovered by the bonding material to allow portions of the cross-buss 316 or the side buss 314 to remain exposed so that electrical connections can be made to these regions of the solar cell structure 304 in future steps (i.e., step 138).

Next the composite solar cell structure 304 is transported to the autoclave module 236 in which step 136, or autoclave steps are performed on the composite solar cell structure 304 to remove trapped gases in the bonded structure and assure that a good bond is formed during step 136. In step 136, a bonded solar cell structure 304 is inserted in the processing region of the autoclave module where heat and high pressure gases are delivered to reduce the amount of trapped gas and improve the properties of the bond between the device substrate 303, back glass substrate, and bonding material. The processes performed in the autoclave are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the device substrate 303, back glass substrate, and bonding material to a temperature that causes stress relaxation in one or more of the components in the formed solar cell structure 304.

Next the solar cell structure 304 is transported to the junction box attachment module 238 in which junction box attachment steps 138 are performed on the formed solar cell structure 304. The junction box attachment module 238, used during step 138, is used to install a junction box 308 (FIG. 3) on a partially formed solar module. The installed junction box 308 acts as an interface between the external electrical components that will connect to the formed solar module, such as other solar modules or a power grid, and the internal electrical connections points, such as the leads, formed during step 131. In one embodiment, the junction box 308 contains one or more connection points so that the formed solar module can be easily and systematically connected to other external devices to deliver the generated electrical power.

Next, the solar cell structure 304 is transported to the device testing module 240 in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells. In step 140, a light emitting source and probing device are used to measure the output of the formed solar cell device by use of one or more automated components that are adapted to make electrical contact with terminals in the junction box 308. If the module detects a defect in the formed device it can take corrective actions or the solar cell can be scrapped.

Next the solar cell structure 304 is transported to the support structure module 241 in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site.

Next the solar cell structure 304 is transported to the unload module 242 in which step 142, or device unload steps are performed on the substrate to remove the formed solar cells from the solar module production line 200.

### Common Laser Scribe Module and Laser Scribe Tools

FIG. 5 is a schematic plan view of the common scribe module 500 according to one embodiment of the present invention. The common scribe module 500 may include a plurality of reading devices 510 located at entry and exit points of the common scribe module 500. In one embodiment, the reading devices 510 are bar code readers, or other optical reading devices, for reading the unique reference designator supplied on each device substrate 303 and communicating identification information associated with the reference designator to the system controller 290. The common scribe module 500 also includes the automation device 281 for generally transporting the device substrate 303 through the common scribe module 500. The automation device 281 may include a plurality of rollers (not shown), actuators (not shown), and other conventional conveyor components, which are all controlled by the system controller 290. As previously set forth, the common scribe module 500 also includes a plurality of laser scribe tools 600. Although FIG. 5 depicts the common scribe module 500 having three laser scribe tools 600, this is not intended to limit the scope of the invention. In other embodiments, the common scribe module 500 may contain more or fewer scribe tools 600 depending on the desired throughput of the production line 200, such as depicted in FIG. 2, for instance.

FIG. 6A is a schematic plan view and FIG. 6B is a schematic, cross-sectional view of a laser scribe tool 600 that may be used for laser scribing a series of trenches (i.e., P1, P2, or P3) in one or more material layers (i.e., front contact layer 310, PV layer 320, or back contact layer 350) deposited on the solar cell substrate 302. In one embodiment, the laser scribe tool 600 generally includes a substrate handling system 610, one or more laser devices 620, and an exhaust assembly 630, all coordinated and controlled by the system controller 290.

In general operation, a device substrate 303 is transferred into the laser scribe tool 600 following a path A. In one embodiment, the device substrate 303 is oriented with the surface having one or more layers (e.g., front contact layer 310, PV layer 320, back contact layer 350) facing upwardly. The device substrate 303 is then passed over the laser devices 620 one or more times while a series of trenches (i.e., P1, P2, or P3) are scribed into the device substrate 303. The device substrate 303 then exits the laser scribe tool 600 following path Aₒ. Although FIG. 6A depicts the substrate 303 following the path Aᵢ to Aₒ, the substrate 303 may follow a path in the opposite direction Aₒ to Aᵢ, depending on commands received from the system controller 290.

FIG. 6C is a schematic depiction of the laser device 620. In one embodiment, each laser device 620 comprises a laser radiation source 621 and a focusing optical module 623 disposed therein. The laser radiation source 621 includes a pumped laser source 622 that emits a light beam to an optical fiber 624 disposed in the focusing optical module 623. The optical fiber 624 serves as a gain medium that is configured to receive a pulse of energy delivered from the pumped laser source 622 having an initial pulse wavelength and an initial pulse energy. When received by the optical fiber 624, the pulse of energy from the pumped laser source 622 is amplified and emitted toward the desired region of the device substrate 303. Suitable examples for the gain medium may be fiber doped with one or more rare earth metals (e.g., actinides, lanthanides), such as erbium, neodymium, ytterbium, thulium, praseodymium, holmium, dysprosium, samarium, or the like. Light emitting atoms, such as rare earth metals, are doped into a core of the optical fiber 624 that confines the light that the atoms emit. A pair of mirrors 625a and 625b may be disposed on each end of the optical fiber 624 to confine the pumped radiation inside the fiber gain medium and allow the emitted radiation to exit therefrom.

In one embodiment, the optical fiber 624 may include a core 626, an internal cladding 627, and an outer cladding 628 as depicted in the schematic, cross-sectional view shown in FIG. 6D. The core 626 may be formed from a ceramic material that has the rare earth metals doped therein. Suitable ceramic containing materials may include silica, silicon containing material, silicon carbon, silicon oxide, and the like. In one embodiment, the rare earth metals selected to be doped into the core 626 are erbium or ytterbium. The internal cladding 627 may comprise a material having a first refractive index, and the outer cladding 628 may be made from a material having a second refractive index different from the first refractive index. A large refractive index contrast between the internal cladding 627 and the outer cladding 628 may enhance light reflection when transmitting through the optical fiber 624, thereby amplifying the laser emitting efficiency. In one embodiment, the internal cladding 627 and the outer cladding 628 may be fabricated from suitable ceramic materials, such a silica glass, silicon carbide, or the like.

Referring back to FIG. 6C, the focusing optical module 623 may also include one or more collimators to collimate radiation from the pumped laser source 622 into a substantially parallel beam. This collimated radiation beam is then focused by at least one lens 629 into a line of radiation directed at the desired region of the device substrate 303. The lens 629 may be any suitable lens, or series of lenses, capable of focusing radiation into a line or spot. In one embodiment, the lens 629 is a cylindrical lens. Alternatively, the lens 629 may be one or more concave lenses, convex lenses, plane mirrors, concave mirrors, convex mirrors, refractive lenses, diffractive lenses, Fresnel lenses, gradient index lenses, or the like.

Referring back to FIGS. 6A and 6B, the system controller 290 controls the power, energy, pulse width, and pulse frequency (among other parameters) of the delivery of energy used to scribe the desired trenches (e.g., P1, P2, or P3) into the respective layer (e.g., front contact layer 310, PV layer 320, or back contact layer 350) in the device substrate 303. In one embodiment, the one or more laser devices 620 are located below the device substrate 303. In one embodiment, a portion of the exhaust assembly 630 is located above the device substrate 303, in order to effectively exhaust material that is ablated or otherwise removed from the device substrate 303 via the respective laser device 620.

In one embodiment, the substrate handling system 610 includes a support structure 605 that is positioned beneath the device substrate 303 and is adapted to support and retain the various components used to perform laser scribing processes on the device substrate 303. In one embodiment, the substrate handling system 610 includes a conveyor system 612 that has a plurality of conventional, automated conveyor belts for positioning and transferring the device substrate 303 within the laser scribe tool 600 in a controlled and automated fashion.

In one embodiment, the substrate handling system 610 further includes one or more substrate grippers 614 for retaining, guiding, and moving the device substrate 303 during laser scribing processes. The substrate grippers 614 are used to grip the edges of the device substrate 303 and include an actuator, such as a linear motor, to translate the device substrate 303 in the Y and −Y directions while the laser devices 620 form the trenches (e.g., P1, P2, or P3) into the desired layers of the device substrate 303.

Referring to FIG. 5, as a device substrate 303 is received into the common scribe module 500, the reference designator assigned to the device substrate 303 is read by the reading device 510, and identification information associated with the reference designator, and thus the device substrate 303 is communicated to the system controller 290. From this information, the system controller 290 may determine which processes the device substrate 303 has undergone, and which scribing process is needed. The system controller 290 may then determine which scribe tool 600 is available and send commands to the automation device 281 to transport the device substrate 303 to the available scribe tool 600. The system controller 290 may also set and control the parameters (e.g., power, pulse frequency, pulse width, pattern of scribe lines) of the laser scribe tool 600 in order to scribe the appropriate lines of trenches (P1, P2, or P3) in the appropriate layer (310, 320, 350) of the device substrate 303. In one embodiment, the system controller 290 determines the process parameters based on the location from which the device substrate 303 is received. Once the laser scribing procedure (108, 116, 120) is completed, the device substrate 303 is transported out of the common scribe module 500 via the automation device 281 controlled by the system controller 290.

As previously mentioned, current state of the art laser ablation techniques used for forming trenches in the front contact layer 310 (or TCO layer) of thin film solar cells require the use of a higher wavelength laser, such as 1064 nm, than that used for the PV layer 320 and back contact layer 350. This is because the lower wavelength lasers, such as conventional 532 nm wavelength laser, are not capable of fully ablating a spot of the TCO material layer with a single pulse. In contrast, the configuration and processes described above with respect to the present invention allow the use of a 532 nm programmable fiber laser at significantly higher pulse frequencies to remove trenches P1 of the TCO material in a single pass. This is possible because the higher pulse frequency capability provides multiple pulses of energy at the same “spot” on the substrate 302, effectively “chipping away” at the TCO layer until the entire “spot” is ablated. Thus, the use of such apparatus and techniques allow the use of a plurality of identical lasers, such as 532 nm wavelength lasers, to scribe lines of the trenches P1, P2, and P2 in the multiple layers of the device substrate 303 without sacrificing throughput of the overall system.

While the foregoing is directed to embodiments of the present invention, other and further embodiments of the invention may be devised without departing from the basic scope thereof, and the scope thereof is determined by the claims that follow.

1. A laser scribe module for scribing a series of trenches in multiple material layers, including at least a front contact layer, a photovoltaic layer, and a back contact layer, deposited on a substrate, comprising:
an automation device configured to receive and transport the substrate within the module;
one or more reading devices configured to scan a unique reference designator assigned to the substrate;
a plurality of laser scribing tools, each configured to emit radiation at substantially the same wavelength; and
a system controller configured to receive information from the one or more reading devices, identify the material layer needing to be scribed, send commands to the automation device to transport the substrate to one of the plurality of laser scribing tools, and configure parameters of the laser scribing tool for scribing the identified material layer.

2. The laser scribe module of claim 1, wherein the wavelength is between about 510 nm and about 560 nm.

3. The laser scribe module of claim 2, wherein the parameters comprise at least a laser pulse frequency.

4. The laser scribe module of claim 3, wherein the material layer identified is a front contact layer and the laser pulse frequency is at least about 300 kHz.

5. The laser scribe module of claim 4, wherein the front contact layer is a transparent conducting oxide layer.

6. The laser scribe module of claim 3, wherein the material layer identified is a photovoltaic layer and the laser pulse frequency is between about 15 kHz and about 30 kHz.

7. The laser scribe module of claim 3, wherein the material layer identified is a back contact layer and the laser pulse frequency is between about 15 kHz and about 30 kHz.

8. The laser scribe module of claim 2, wherein each laser scribing tool comprises a fiber based pulse amplifier laser.

9. A process for scribing lines in multiple layers of a solar cell device, comprising:
receiving a substrate having one or more material layers disposed thereon into a laser scribe module, wherein the laser scribe has a plurality of laser scribe tools disposed therein, each laser scribe tool configured to emit radiation at substantially the same wavelength;
transferring the substrate to an available laser scribe tool via an automation device and a system controller;
setting parameters of the available laser scribe tool based on a top material layer disposed on the substrate via the system controller, wherein the top material layer is selected from the list consisting of a front contact layer, a photovoltaic layer, and a back contact layer; and
scribing a series of lines into the top material layer via the available laser scribe tool and the system controller.

10. The process of claim 9, wherein the wavelength is between about 510 nm and about 560 nm.

11. The process of claim 10, wherein the parameters include at least a laser pulse frequency.

12. The process of claim 11, wherein the top layer is a front contact layer and the laser pulse frequency is at least about 300 kHz.

13. The process of claim 11, wherein the top layer is a photovoltaic layer and the laser pulse frequency is between about 15 kW and about 30 kW.

14. The process of claim 11, wherein the top layer is a back contact layer and the laser pulse frequency is between about 15 kW and about 30 kW.

15. A system for fabricating solar cell modules, comprising:
a loading module configured to receive a substrate having a front contact layer disposed thereon;
a first processing module configured to receive the substrate having the front contact layer disposed thereon with a series of trenches scribed through the front contact layer and deposit a photovoltaic layer over the scribed front contact layer;
a second processing module configured to receive the substrate having the photovoltaic layer disposed thereon with a series of trenches scribed through the photovoltaic layer and deposit a back contact layer over the scribed photovoltaic layer;
a common laser module having a plurality of laser tools for scribing the series of lines in each layer deposited on the substrate, wherein each laser tool is configured to emit radiation at substantially the same wavelength; and
a system controller configured to set and control parameters of each of the laser tools based on the top layer deposited on the substrate needing to be scribed.

16. The system of claim 15, wherein the wavelength is between about 510 and about 560.

17. The system of claim 16, wherein the parameters include at least a laser pulse frequency.

18. The system of claim 17, wherein the top layer is the front contact layer and the laser pulse frequency is at least 300 kHz.

19. The system of claim 17, wherein the top layer is the photovoltaic layer and the laser pulse frequency is between about 15 kW and about 30 kW.

20. The system of claim 17, wherein the top layer is the back contact layer and the laser pulse frequency is between about 15 kW and about 30 kW.

21. The system of claim 17, wherein the common laser module is configured to receive the substrate from the loading module, the first processing module, and the second processing module, and wherein the system controller is configured to determine the top layer on the substrate needing to be scribed based on the processing module from which the substrate is received.

22. The system of claim 17, further comprising one or more reading devices configured to scan a unique reference designator assigned to the substrate, wherein the system controller is configured to receive information from the one or more reading devices, identify the top material layer needing to be scribed, select an available laser scribing tool, and configure the parameters of the laser scribing tool for scribing the identified top material layer.

23. A process for fabricating solar cell modules, comprising:
receiving a substrate having a transparent conducting oxide layer deposited thereon into a common laser module having a plurality of laser scribing tools, wherein each laser scribing tool is configured to emit radiation at substantially the same wavelength;
transferring the substrate to a first available laser scribing tool via an automation device and a system controller;
setting at least a laser pulse frequency of the first available laser scribing tool via the system controller;
scribing a series of trenches through the transparent conducting oxide layer;
transferring the substrate into a first processing module having at least one cluster tool with at least one chamber via the automation device;
depositing one or more photovoltaic layers over the scribed transparent conducting oxide layer;
transferring the substrate having the one or more photovoltaic layers disposed thereon to a second available laser scribing tool within the common laser module via the automation device;
setting at least a laser pulse frequency of the second available laser scribing tool via the system controller;
scribing a series of trenches through the one or more photovoltaic layers;
transferring the substrate into a second processing module having at least one deposition chamber;
depositing a back contact layer over the scribed photovoltaic layers;
transferring the substrate having the back contact layer deposited thereon to a third available laser scribing tool within the common laser module via the automation device;
setting at least a laser pulse frequency of the third available laser scribing tool via the system controller; and
scribing a series of trenches through the back contact layer.

24. The process of claim 23, wherein the wavelength is between about 510 nm and about 560 nm.

25. The process of claim 24, wherein the laser pulse frequency of the first available laser scribing tool is set at least about 300 kHz, wherein the laser pulse frequency of the second available laser scribing tool is set between about 15 kHz and about 30 kHz, and wherein the laser pulse frequency of the third available laser scribing tool is set between about 15 kHz and about 30 kHz.
